(19) United States
(12) Patent Application Publication
(10) Pub. No.: US 2003/0112616 A1
(43) Pub. Date: Jun. 19, 2003

(54) Layered circuit boards and methods of production thereof

(76) Inventor: Yutaka Doi, Minnetonka, MN (US)

Correspondence Address: ROBERT D. FISH; RUTAN & TUCKER, LLP, P.O. BOX 1950, 611 ANTON BLVD., 14TH FLOOR, COSTA MESA, CA, 92628-1950, US

(21) Appl. No.: 10/033,968

(22) Filed: Dec. 18, 2001

(51) Int. Cl. H05K 9/00

(52) U.S. Cl. 361/818

(57) ABSTRACT

Compositions and methods are provided whereby electronic layered components or stacks may be produced that comprise a) a substrate layer; b) an electronic component; and c) an electromagnetic interference shielding component, wherein the component comprises a first insulating layer, an electrically conductive layer, and a second insulating layer. The layered component or stack comprising an electronic component and an electromagnetic interference shielding component may be produced by: a) providing a substrate layer, wherein the substrate layer comprises at least one layer of material; b) coupling an electronic component to the substrate layer; c) applying a conformal electromagnetic interference shielding component to the substrate layer, wherein applying the step of an electromagnetic interference shielding component further comprises: 1) applying a first insulating layer to the electronic component; 2) patterning the first insulating layer; 3) applying an electrically conductive layer to the patterned first insulating layer; 4) applying a second insulating layer to the electrically conductive layer; and 5) curing the shielding component.

### FIELD OF THE INVENTION

The field of the invention is layered electronic components.

### BACKGROUND OF THE INVENTION

Electronic components are used in ever increasing numbers of consumer and commercial electronic products. Examples of some of these consumer and commercial products are televisions, computers, cell phones, pagers, a palm-type personal organizer, portable radios, car stereos, or remote controls. As the demand for these consumer and commercial electronics increases, there is also a demand for those same products to become smaller and more portable for the consumers and businesses.

As a result of the size decrease in these products, the components that comprise the products must also become smaller. Examples of some of those components that need to be reduced in size or scaled down are printed circuit or wiring boards, resistors, capacitors, wiring, keyboards, touch pads, and chip packaging.

Components, therefore, are being broken down and investigated to determine if there are better building materials, better design strategies and methods that will allow those components to be scaled down to accommodate the demands for smaller electronic components, while keeping capital costs low. In layered components, one goal appears to be decreasing the number or the size of the layers or perhaps incorporating several functions into one or two layers. This task can be difficult, however, given that several of the layers and components of the layers should generally be present in order to operate the component.

One such component is an electromagnetic interference shield. Electromagnetic interference shields prevent electromagnetic interference from reaching the individual components. Typical electromagnetic interference shields are constructed out of metal “cans”, such as that found in Lin. Lin et al. discloses in U.S. Pat. No. 6,220,895 (issued Apr. 24, 2001) a process that uses a “stamped” or formed metal “can” to non-conformally surround an insulative housing and shield the housing from electromagnetic interference. The metal shield, after being stamped, is fitted onto and around the housing; however, it is not designed to be a conformal layer of material and therefore can be bulky and difficult to process. Further, it is difficult to place a component such as the one described in Lin in a printed circuit board application where multiple layers are built up and processed.

Chion in U.S. Pat. No. 6,168,467 (issued Jan. 2, 2001) discloses a method of eliminating the apparent metal waste that might be generated in a process, such as the one disclosed in Lin, by using a two-piece housing that can fit a component better than a metal can. Even though the two-piece housing can better surround a component, it is still not conformal to the component that it is surrounding and can be difficult to process into a printed circuit board or similar application.

Chang in U.S. Pat. No. 6,207,089 (issued Mar. 27, 2001) and U.S. Pat. No. 6,202,276 (issued Mar. 20, 2001) discloses a method of and an apparatus for forming a molded component that shields electromagnetic interference from another component; however, the molded component is not conformal to the individual electronic component with which it will be coupled, but is instead conformal to the original mold.

Thus, there is a continuing need to a) design and produce layered materials that can shield components from electromagnetic interference, that are conformal to the underlying components, and yet can still minimize the size and number of layers in the overall layered stack or printed circuit board, and b) develop reliable and cost-efficient methods of producing desired layered materials and components comprising those layered materials.

### SUMMARY OF THE INVENTION

Electronic layered components or stacks may be produced that comprise a) a substrate layer; b) an electronic component; and c) a conformal electromagnetic interference shielding component, wherein the shielding component comprises a first patterned insulating layer, an electrically conductive layer, and a second insulating layer.

The layered component or stack comprising an electronic component and a conformal electromagnetic interference shielding component maybe produced by: A method of producing a layered stack having at least one electromagnetic interference shielding layer, comprising: a) providing a substrate layer, wherein the substrate layer comprises at least one layer of material; b) coupling an electronic component to the substrate layer; c) applying a conformal electromagnetic interference shielding component to the substrate layer, wherein applying the step of an electromagnetic interference shielding component further comprises: 1) applying a first insulating layer to the electronic component; 2) patterning the first insulating layer; 3) applying an electrically conductive layer to the patterned first insulating layer; 4) applying a second insulating layer to the electrically conductive layer; and 5) curing the shielding component.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

FIG. 1 is a schematic diagram of a first embodiment of a layered stack of the present invention.

FIG. 2 is a schematic diagram of a second embodiment of the layer stack of the present invention.

FIG. 3 is a flowchart showing a preferred method of one aspect of the present invention.

FIG. 4 is a schematic diagram of a third embodiment of a layered stack of the present invention.

### DETAILED DESCRIPTION

Conventional layered materials that comprise electronic components are generally quite susceptible to electromagnetic interference. Insulator layers can be applied to the components, but these layers are not electrically conductive. Therefore, in order to build a layered material that insulates the components from electromagnetic interference, as well as provide some electrical conductivity, several specialized layers or sets of layers must be applied to the component, such as “metal cans”. These metal cans or metal coverings are usually made from nickel, copper or silver and can be difficult to reliably and reproducibly apply to the layered materials and components, as well as being large in size, costly, and time consuming in the overall assembly.

Layered electronic stacks and components generally contemplated herein are assembled such that a layered stack comprises at least one layer that is not only electrically conductive but also effectively shields electromagnetic interference from the underlying or overlying component. The layered electronic stacks and components formed herein are also easier to assemble than conventional stacks and components, as well as taking less time and capital expenditure to produce.

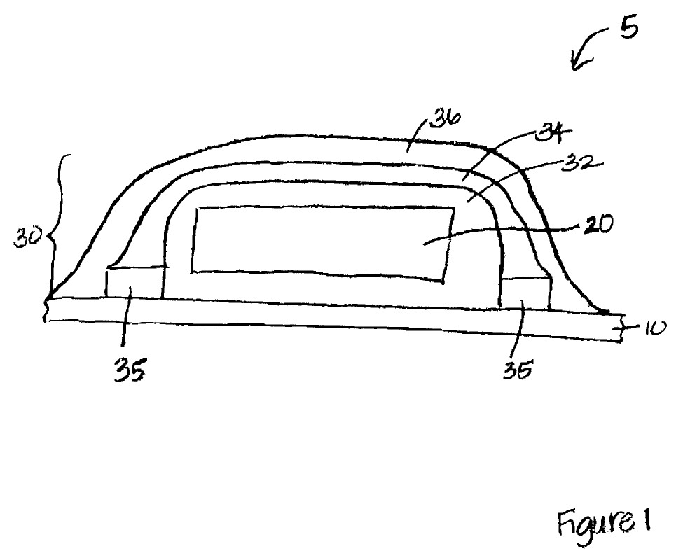

FIG. 1 shows a layered electronic stack 5, such as a printed circuit board, of the present invention. The layered electronic stack 5 generally comprises the following: a) a substrate layer 10, b) at least one electronic component 20, and c) a conformal electromagnetic shielding component 30, wherein the component 30 comprises a first patterned insulating layer 32, an electrically conductive layer 34, a pair of ground pads 35, and a second insulating layer 36.

Electronic components 20, as contemplated herein, are generally thought to comprise any single or layered component that can be utilized in an electronic-based product. The phrase “layered electronic stack” can be used interchangeably with the phrase “electronic component” when the electronic component is a layered component. Contemplated electronic components comprise circuit boards, chip packaging, dielectric components of circuit boards, printed-wiring boards, and other components of circuit boards, such as capacitors, inductors, and resistors.

As used herein, the term “electronic component” also means any device or part that can be used in a circuit to obtain some desired electrical action. Electronic components contemplated herein may be classified in many different ways, including classification into active components and passive components. Active components are electronic components capable of some dynamic function, such as amplification, oscillation, or signal control, which usually requires a power source for its operation. Examples are bipolar transistors, field-effect transistors, and integrated circuits. Passive components are electronic components that are basically static in operation, i.e., are ordinarily incapable of amplification or oscillation, and usually require no power for their characteristic operation. Examples are conventional resistors, capacitors, inductors, diodes, rectifiers and fuses.

Electronic components contemplated herein may also be classified as conductors, semiconductors, or insulators. Here, conductors are components that allow charge carriers (such as electrons) to move with ease among atoms as in an electric current. Examples of conductor components are circuit traces and vias comprising metals. Insulators are components where the function is substantially related to the ability of a material to be extremely resistant to conduction of current, such as a material employed to electrically separate other components, while semiconductors are components having a function that is substantially related to the ability of a material to conduct current with a natural resistivity between conductors and insulators. Examples of semiconductor components are transistors, diodes, some lasers, rectifiers, thyristors and photosensors.

Electronic components contemplated herein may also be classified as power sources or power consumers. Power source components are typically used to power other components, and include batteries, capacitors, coils, and fuel cells. Power consuming components include resistors, transistors, ICs, sensors, and the like.

Still further, electronic components contemplated herein may also be classified as discreet or integrated. Discreet components are devices that offer one particular electrical property concentrated at one place in a circuit. Examples are resistors, capacitors, diodes, and transistors. Integrated components are combinations of components that that can provide multiple electrical properties at one place in a circuit. Examples are ICs, i.e., integrated circuits in which multiple components and connecting traces are combined to perform multiple or complex functions such as logic.

As used herein the various forms of the terms “layered” or “multilayered”, as applied to components, means that the functionality of the component arises from having juxtaposed layers of different materials. For example, a typical P-N-P transistor is considered herein to be a multilayered component because its functions arise from the juxtaposition of P and N doped semiconductor layers. On the other hand, a conductive trace on a circuit board would not generally be considered to be multilayered by itself, even if the trace had been manufactured by successive deposits of the conductive material, because each successive layer merely increases the current carrying capacity, rather than altering the functionality of the trace.

Electronic-based products can be “finished” in the sense that they are ready to be used in industry or by other consumers. Examples of finished consumer products are a television, a computer, a cell phone, a pager, a palm-type organizer, a portable radio, a car stereo, and a remote control. Also contemplated are “intermediate” products such as circuit boards, chip packaging, and keyboards that are potentially utilized in finished products.

Electronic products may also comprise a prototype component, at any stage of development from conceptual model to final scale-up mock-up. A prototype may or may not contain all of the actual components intended in a finished product, and a prototype may have some components that are constructed out of composite material in order to negate their initial effects on other components while being initially tested.

Electronic products and components may comprise layered materials, layered components, and components that are laminated in preparation for use in the component or product. Layers that include or comprise electronic components can make up the finished layered component or product.

The substrate layer 10, as described earlier, may comprise any desirable substantially solid material. The substrate layer 10 functions in a conventional component to provide a basis or support for the layered materials that are built up or “laid up” on the substrate layer 10. It may also function as a dielectric material or as a bonding point for layers below the substrate layer 10. The substrate 10 may also form several functions. For example, as described herein, the substrate 10 may form merely the basis for building up layers, or the substrate 10 may not only serve as a basis for building up layers, but may also serve as an insulating layer for the component above it.

Particularly desirable substrate layers 10 comprise films, glass, ceramic, plastic, metal or coated metal, composite material, or a combination thereof. In preferred embodiments, the substrate 10 comprises a silicon or germanium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and it's oxides), a polymer-based packaging or board interface such as found in a polyimide-based flex package, lead or other metal alloy solder ball surface, glass and polymers such as polyimides, BT (triazine/bismalemide), and FR4. In more preferred embodiments, the substrate 10 comprises a material common in the packaging and circuit board industries such as silicon, copper, glass, and another polymer.

The substrate layer 10 may also comprise a plurality of voids if it is desirable for the material to be nanoporous instead of continuous. Voids are typically spherical, but may alternatively or additionally have any suitable shape, including tubular, lamellar, discoidal, or other shapes. It is also contemplated that voids may have any appropriate diameter. It is further contemplated that at least some of the voids may connect with adjacent voids to create a structure with a significant amount of connected or “open” porosity. The voids preferably have a mean diameter of less than 1 micrometer, and more preferably have a mean diameter of less than 100 nanometers, and still more preferably have a mean diameter of less than 10 nanometers. It is further contemplated that the voids may be uniformly or randomly dispersed within the substrate layer. In a preferred embodiment, the voids are uniformly dispersed within the substrate layer 10.

Substrate layers 10 contemplated herein may also comprise at least two layers of materials. The first layer of material comprising the substrate layer 10 may include the substrate materials previously described. Other layers of material comprising the substrate layer 10 may include layers of metals, polymers, monomers, organic compounds, inorganic compounds, organometallic compounds, continuous layers and nanoporous layers. In preferred embodiments, the substrate layer 10 comprises a wafer, such as a silicon wafer, coupled with at least one layer of insulating material. In other preferred embodiments, the substrate layer 10 comprises a wafer coupled with at least one layer of insulating material and at least one layer of metal, such as a metal trace or patterned metal layer. The metal trace is designed to electronically connect the substrate layer with other layers, as well as providing impedance control.

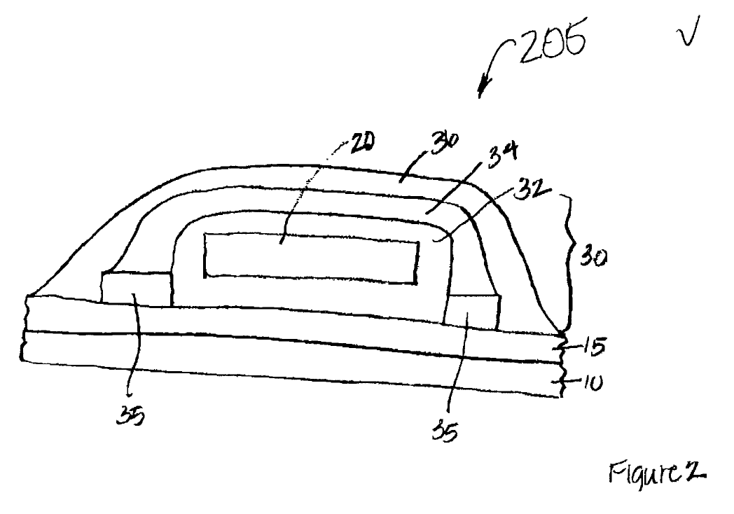

As mentioned, an insulating material or insulator layer 15 can be coupled to the substrate layer 10, as shown in the electronic stack 205 of FIG. 2. The insulator layer 15 is designed to insulate, electronically and environmentally, any components in the layer from other components or surrounding layers, to withstand the environment, such as heat and humidity, and to act as an efficient resistor. The insulator layer generally comprises any suitable and desirable material depending on the needs of the customer and the design needs of the component. In preferred embodiments, the insulator or insulating material comprises a resin-based material or thermosetting plastic that can be imaged and etched.

Patterned metal layers or metal traces function as electronic connectors between the layered components, and in some cases as impedance controllers. Each layer must be functionally connected in order for the electronic component to be efficient and operable. Generally, the metal layers or traces comprise any metal or conductive material that acts as a metal. The metal layers or traces usually comprise copper or nickel.

Suitable materials that can be used in additional substrate layers 10 comprise any material with properties appropriate for a printed circuit board or other electronic component, including polymers, monomers, pure metals, alloys, metal/metal composites, metal ceramic composites, metal polymer composites, cladding material, laminates, conductive polymers and monomers, as well as other metal composites.

As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include titanium, silicon, cobalt, copper, nickel, zinc, vanadium, aluminum, chromium, platinum, gold, silver, tungsten, molybdenum, cerium, promethium, and thorium. More preferred metals include titanium, silicon, copper, nickel, platinum, gold, silver and tungsten. Most preferred metals include titanium, silicon, copper and nickel. The term “metal” also includes alloys, metal/metal composites, metal ceramic composites, metal polymer composites, as well as other metal composites.

Contemplated polymers may also comprise a wide range of functional or structural moieties, including aromatic systems, and halogenated groups. Furthermore, appropriate polymers may have many configurations, including a homopolymer, and a heteropolymer. Moreover, alternative polymers may have various forms, such as linear, branched, super-branched, or three-dimensional. The molecular weight of contemplated polymers spans a wide range, typically between 400 Dalton and 400000 Dalton or more.

As used herein, the term “monomer” refers to any chemical compound that is capable of forming a covalent bond with itself or a chemically different compound in a repetitive manner. The repetitive bond formation between monomers may lead to a linear, branched, super-branched, or three-dimensional product. Furthermore, monomers may themselves comprise repetitive building blocks, and when polymerized the polymers formed from such monomers are then termed “blockpolymers”. Monomers may belong to various chemical classes of molecules including organic, organometallic or inorganic molecules. The molecular weight of monomers may vary greatly between about 40 Dalton and 20000 Dalton. However, especially when monomers comprise repetitive building blocks, monomers may have even higher molecular weights. Monomers may also include additional groups, such as groups used for crosslinking.

As used herein, the term “crosslinking” refers to a process in which at least two molecules, or two portions of a long molecule, are joined together by a chemical interaction. Such interactions may occur in many different ways including formation of a covalent bond, formation of hydrogen bonds, hydrophobic, hydrophilic, ionic or electrostatic interaction. Furthermore, molecular interaction may also be characterized by an at least temporary physical connection between a molecule and itself or between two or more molecules.

Thus, it is contemplated that the substrate layer 10 may comprise a single layer of conventional substrate material. It is alternatively contemplated that the substrate layer 10 may comprise several layers, along with the conventional substrate material, that function to build up part of layered electronic component 5.

Once the substrate layer 10 and the electronic component 20 are coupled, the conformal electromagnetic interference shielding component 30 is added to the layered stack. A preferred conformal electromagnetic interference shielding component 30 comprises a first patterned insulating layer 32, an electrically conductive layer 34, a pair of ground pads 35, and a second insulating layer 36. Also, a preferred shielding component 30 is conformal—meaning that the component conforms to the shape of the underlying substrate/electronic component stack as it is applied to the stack or immediately after application to the stack, unlike the Lin, Chiou or Chuang patents previously described. It is further preferred that the conformal shielding component 30 be able to substantially shield electromagnetic interference from the underlying or overlying components or layers. As used herein, the phrase “substantially shield” means that the component 30 can shield at least about 75% of the electromagnetic interference from the underlying or overlying components or layers. In more preferred embodiments, the component 30 can shield at least about 85% of the electromagnetic interference from the underlying or overlying components or layers. And in most preferred embodiments, the component 30 can shield over about 90% of the electromagnetic interference from the underlying or overlying components or layers.

The first patterned insulating layer 32 and the second insulating layer 36 are intended to provide electrical insulation for the underlying electronic component 20 (as in the case of the first insulating layer 32) and for the overlying and also underlying electrically conductive layer 34 (as in the case of the first insulating layer 32 and the second insulating layer 36, respectively). FIG. 1 shows the relationship between the electronic component 20, the first insulating layer 32, the electrically conductive layer 34 and the second insulating layer 36. The first patterned insulating layer 32 is further intended to provide a base pattern for the application of the electrically conductive layer 34.

The first patterned insulating layer 32 and the second insulating layer 36 may comprise any suitable insulating material, such as those already discussed herein. It is however not contemplated that the insulating layers comprise solely adhesive materials. Adhesive materials may be coupled to the insulating layers; however, it is not contemplated that the adhesive layer is the insulating layer. It is further contemplated that the first and second insulating layers may comprise the same or entirely different insulating materials. The determination of the proper materials for the first and second insulating layers is dependent on the needs of the customer and the electronic and spatial requirements of the layered stack or layered component.

The ground pads 35 are physically coupled to both the electronic component 20 and the first insulating layer 32 and provide a grounding source for the component and electrically conductive layered material.

The electrically conductive layer 34 is sandwiched between the first and second insulating layers 32 and 36, respectively, and is designed to perform as its name suggests—as a layer of material that can conduct electrons. The electrically conductive layer 34 could also be designed to simultaneously or solely conduct photons, as in the case of wave-guide materials. It is contemplated that the electrically conductive layer 34 may comprise any suitable material, as long as the material is capable of conducting electrons, photons and/or both electrons and photons. Therefore, the electrically conductive layer 34 may comprise polymers, monomers, pure metals, alloys, metal/metal composites, metal ceramic composites, metal polymer composites, cladding material, conductive laminates, conductive polymers and monomers, as well as other metal composites, which have been described previously.

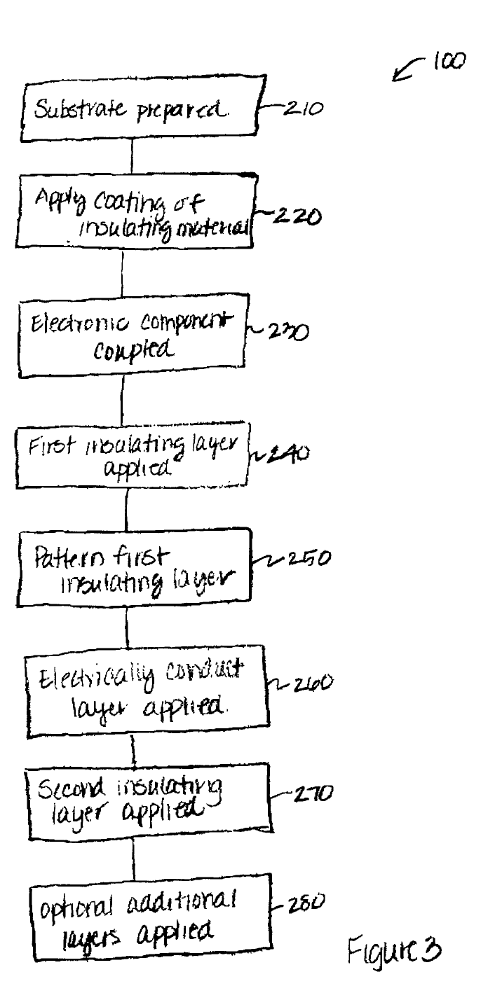

FIG. 3 shows a preferred method 100 of preparing the layered component comprising an electronic component and an electromagnetic interference shielding component. In step 210 a substrate layer 10 is prepared that forms the basis for the component contemplated herein. As mentioned earlier, the substrate layer 10 may comprise more than one layer of material. In step 220, a coating of insulating material is applied to the original substrate layer and cured. An electronic component 20 and pair of ground pads 35 are then coupled to the substrate 10 in step 230. In step 240 a first insulating layer is applied 240 to the electronic component 20 and cured. The exposed surface of the first insulating layer is patterned in step 250. The electrically conductive layer 34 is applied in step 260 to the exposed and patterned surface of the first insulating layer 32 and cured. A second insulating layer 36 is applied in step 270 to the electrically conductive layer 34 and cured. In step 280 additional layers can then be added to the finished insulator layer 36 if desired.

Each of the layers described herein, including the insulating layers and the electrically conductive layers, can be applied to each other layer by any number of conventional processes, including spray-coating, electroless plating, dipping, spinning-on, pouring on, vapor deposition, and/or chemical vapor deposition. It is also contemplated that the process for applying the insulating layers might be different than the process for applying the electrically conductive layer, which is understandable given the range in materials that can be used for each layer.

Each of the layers described herein, including the insulating layers and the electrically conductive layers, can be patterned by any number of conventional or novel processes, such as laser direct writing, masking, chemical or physical etching, molding, projection, or by application of heat. As mentioned herein, it is intended that the first insulating layer 32 be patterned before the electrically conductive layer 34 is applied. In preferred embodiments, the second insulating layer 36 is not patterned as it is applied to the electrically conductive layer 34, but the second insulating layer 36 may be patterned subsequent to application in order to lay down additional layers. In other preferred embodiments, the second insulating layer 36 maybe patterned as it is applied to the electrically conductive layer 34. Whether the second insulating layer 36 is patterned or not patterned as applied to the electrically conductive layer 34 depends on the needs and requirements of the component, the finished product that will house and utilize the component and the customer.

A layer of laminating material or cladding material can be coupled to the layered electronic stack 5 depending on the specifications required by the component. Laminates are generally considered fiber-reinforced resin dielectric materials. Cladding materials are a subset of laminates that are produced when metals and other materials, such as copper, are incorporated into the laminates. (Harper, Charles A., Electronic Packaging and Interconnection Handbook, Second Edition, McGraw-Hill (New York), 1997.)

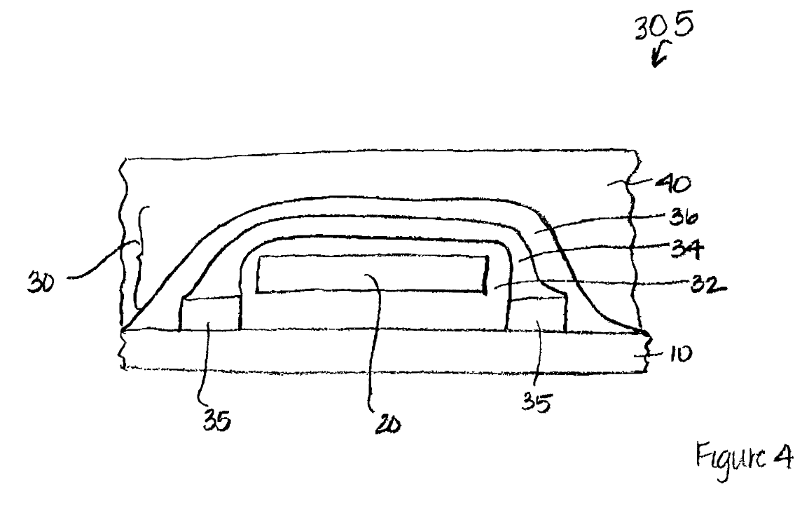

Additional layers of material 40 may be coupled to the electromagnetic shielding component 30 in order to continue building a layered component or printed circuit board 305, as shown in FIG. 4. It is contemplated that the additional layers 40 will comprise materials similar to those already described herein, including metals, metal alloys, composite materials, polymers, monomers, organic compounds, inorganic compounds, organometallic compounds, resins, adhesives and optical wave-guide materials.

Bonding materials may also be used to produce the layered component and may comprise any suitable adhesive, resin, laminate, bond-ply, polymer, monomer, or pre-preg material. It is contemplated that bonding materials can and will act as a dielectric material once the layered stack 5 is cured. In contemplated embodiments, the bonding materials comprise FR4 epoxy, cyanate esters, polyimides, and glass reinforced compounds. In more preferred embodiments, the bonding materials comprise one of FR4 or cyanate ester.

It is contemplated that the layered stack 5 and/or each individual layer can be cured to its final form before or after each additional layer is applied to the stack. Although in preferred embodiments the layered stack 5 is cured using heat, many other methods are contemplated, including catalyzed and uncatalyzed methods. Catalyzed methods may include general acid- and base catalysis, radical catalysis, cationic- and anionic catalysis, and photocatalysis. For example, a polymeric structure may be formed by UV-irradiation, addition of radical starters, such as ammoniumpersulfate, and addition of acid or base. Uncatalyzed methods include application of pressure, or application of heat at subatmospheric, atmospheric or super-atmospheric pressure.

Although several different materials and preferred combinations have been previously described for the components of the layered stack 5, it should be realized that the composition of the layered stack 5 is directly dependent on the needs of the customer, the component or the product.

Thus, specific embodiments and applications of electronic components comprising conformal electromagnetic interference shielding components that are electrically conductive have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. A layered stack, comprising:
a substrate layer;
an electronic component; and
a conformal electromagnetic interference shielding component, wherein the shielding component comprises a first patterned insulating layer conformed to the electronic component, an electrically conductive layer, and a second insulating layer.

2. The layered stack of claim 1, further comprising at least one additional layer coupled to the second insulator layer.

3. The layered stack of claim 1, wherein the substrate layer is a printed circuit board.

4. The layered stack of claim 1, wherein the substrate layer comprises at least two layers.

5. The layered stack of claim 1, wherein the conformal electromagnetic interference shielding layer can shield at least about 75% of the electromagnetic interference from an overlying or underlying component.

6. The layered stack of claim 5, wherein the conformal electromagnetic interference shielding layer can shield at least about 85% of the electromagnetic interference from an overlying or underlying component.

7. An electronic product comprising the layered stack of claim 1.

8. A method of producing a layered stack having at least one electromagnetic interference shielding layer, comprising:
providing a substrate layer, wherein the substrate layer comprises at least one layer of material;
coupling an electronic component to the substrate layer;
applying a conformal electromagnetic interference shielding component to the substrate layer, wherein the step of applying an electromagnetic interference shielding component further comprises:
applying a first insulating layer to the electronic component;
patterning the first insulating layer;
applying an electrically conductive layer to the patterned first insulating layer;
applying a second insulating layer to the electrically conductive layer; and
curing the shielding component.

9. The method of claim 8, further comprising coupling at least one additional layer to the layered stack.

10. An electronic product formed from the method of claim 9.

11. The product of claim 10, wherein the product is a printed circuit board.
